(19) United States
(12) Patent Application Publication
(10) Pub. No.: US 2013/0278273 A1
(43) Pub. Date: Oct. 24, 2013

(54) METHOD AND DEVICE FOR DETECTING SHORT CIRCUIT

(71) Applicants: Heike Barlag, Nuremberg (DE); Johannes Reinschke, Nuremberg (DE)

(72) Inventors: Heike Barlag, Nuremberg (DE); Johannes Reinschke, Nuremberg (DE)

(73) Assignee: SIEMENS AKTIENGESELLSCHAFT, Munich (DE)

(21) Appl. No.: 13/880,650

(22) PCT Filed: Oct. 20, 2011
(86) PCT No.: PCT/EP11/68352

§ 371 Date: Jul. 10, 2013

(30) Foreign Application Priority Data
Oct. 21, 2010 (DE) 102010042750.0

(51) Int. Cl. G01R 31/02

(52) U.S. Cl. CPC G01R 31/025
USPC 324/537

(57) ABSTRACT

In a charge cable which can be connected to an electric charging device to charge a battery of an electric vehicle, a method for detecting a short-circuit selects a first voltage value for a test voltage. By applying this test voltage to the charge cable, testing is carried out to determine whether there is a short-circuit , a fault signal is output; if there is a no short-circuit, the test voltage is increased incrementally up to a maximum voltage value. The increased test voltage is used to test whether there is a short-circuit in the charge cable or in the contact connected to the charge cable.

### CROSS REFERENCE TO RELATED APPLICATIONS

This application is the U.S. national stage of International Application No. PCT/EP2011/068352, filed Oct. 20, 2011 and claims the benefit thereof. The International Application claims the benefits of German Application No. 1020100042750.0 filed on Oct. 21, 2010, both applications are incorporated by reference herein in their entirety.

### BACKGROUND

Described below are a method and an apparatus for detecting a short circuit in a charging cable which can be connected to an electrical charging device for the purpose of charging a battery of an electric vehicle.

The number of electrically driven vehicles (electric vehicles) on the road will presumably increase to a great extent in the near future. There will then be a need for a large number of charging devices both in public places and on private land in order to recharge the batteries of these electric vehicles when required.

The international patent application WO 2010/032320 A1 discloses an electric vehicle and a charging device of this type. This electric vehicle has an apparatus in order to check electric lines laid inside the electric vehicle for short circuits.

For the electrical charging devices, it is conceivable that a charging cable which is used for connecting the electric vehicle to the charging device is not permanently connected to the charging device but rather is carried onboard the electric vehicle and is connected to a socket on the charging device when required. In this situation, the case may arise that a faulty charging cable having a short circuit is connected to the charging device.

### SUMMARY

Described below are a method and an apparatus which can be used to safely and reliably detect a short circuit in a charging cable which can be connected to an electrical charging device.

The method is for detecting a short circuit in a charging cable which can be connected to an electrical charging device for the purpose of charging a battery of an electric vehicle, wherein the method involves
a first voltage value being chosen for a test voltage,
this test voltage being applied to the charging cable in order to test whether there is a short circuit in the charging cable or in a contact connected to the charging cable,
a fault signal being output in the event of there being a short circuit,
the test voltage being increased in steps up to a maximum voltage value in the event of there being no short circuit, and the increased test voltage being used to respectively test whether there is a short circuit in the charging cable or in the contact connected to the charging cable.

In this case, it is particularly advantageous that the test voltage is increased in steps up to a maximum voltage value in the event of there being no short circuit, and this increased test voltage is used to respectively test whether there is a short circuit in the charging cable or in the contact connected to the charging cable (for example in the charging socket of the electric vehicle that is connected to the charging cable). This method is advantageously used to detect even short circuits which do not occur until after a particular voltage level, which are not noticeable at low test voltages, however.

For the purposes of this patent application, “there being a short circuit” is understood to mean a decrease in the insulation resistance between conductors of the charging cable or between contacts below the admissible extent, with the result that an unwanted current flows between these conductors or contacts. Such a decrease in the insulation resistance can occur on account of damage to the insulating material, for example, or on account of soiling on the contacts. In this case, damage to the insulating material or soiling is conceivable in which the insulation properties are still sufficient at low voltages but at higher voltages are no longer sufficient for safe insulation of the conductors and contacts.

The method can be terminated with the result of there being no short circuit when the test voltage has reached the maximum voltage value and the test voltages have each detected that there is no short circuit. Advantageously, the method is not terminated until all test voltages and hence also the test voltage of the maximum voltage value have each detected that there is no short circuit (i.e. no short circuit has been detected).

In this case, the method may proceed such that a test is performed to determine whether there is a short circuit in the charging cable or in the contact connected to the charging cable by
charging a capacitor with the test voltage,
applying the test voltage which is present on the capacitor to the charging cable,
monitoring the voltage which is present on the charging cable for a predetermined period of time,
detecting that there is a short circuit when a voltage change (in the voltage which is present on the charging cable) which occurs during the period of time exceeds a predetermined threshold value, or
detecting that there is no short circuit when the voltage change(in the voltage which is present on the charging cable) which occurs during the period of time does not exceed a predetermined threshold value.

This advantageously makes it a very simple matter to detect whether or not there is a short circuit. For this purpose, it is sufficient for the voltage which is present on the charging cable to be monitored only during the period of time and for it to be established whether a voltage change occurs and whether the absolute value of this voltage change exceeds a predetermined threshold value. This can be implemented in a technically very simple manner by a voltage sensor and an electronic voltage monitoring circuit, for example.

The method may be designed such that the first voltage value is between 1 volt and 42 volts.

The method may also be designed such that the maximum voltage value is between 100% and 400% of the maximum charge voltage of the battery of the electric vehicle. This advantageously ensures that no short circuits occur even with voltages in the order of magnitude of the charge voltage of the battery and above.

The method may be implemented such that at the beginning of the method the charging cable is connected to a contact of the electric vehicle, but a flow of current between the contact of the electric vehicle and a battery of the electric vehicle is initially prevented (in the electric vehicle).

In this case, it is particularly advantageous that this method can be used to check not only the charging cable but also, at the same time, additionally the contact of the electric car (e.g. the charging socket or socket or charging jack) for the presence of a short circuit.

It is also advantageous that a flow of current between the contact of the electric car and the battery of the electric car is initially prevented. This ensures that the test voltage is not influenced by the battery, which has an initially unknown charge state.

The method may also be designed such that a current flow enable signal is not sent from the charging device to the electric vehicle until after the method has been terminated with the result of there being no short circuit (whereupon a flow of current between the contact of the electric vehicle and the battery of the electric vehicle can be permitted at the electric vehicle end). This advantageously ensures that a flow of current between the contact and the battery is not permitted until it has been detected that there is no short circuit in the charging cable or contact.

The apparatus is for detecting a short circuit in a charging cable which can be connected to an electrical charging device for the purpose of charging a battery of an electric vehicle, wherein this apparatus is designed to carry out the method described above.

The advantages of this apparatus correspond to the advantages cited above in connection with the method.

This apparatus may be part of the charging device (external to the vehicle) for charging the battery of the electric vehicle.

This apparatus may be designed such that the capacitor used for applying the test voltage to the charging cable is an element of a low-pass filter via which the current flowing through the charging cable flows.

This embodiment of the apparatus advantageously requires no additional capacitor, but rather a capacitor which is present anyway as an element of a low-pass filter is also used for the short-circuit detection.

### BRIEF DESCRIPTION OF THE DRAWINGS

These and other aspects and advantages will become more apparent and more readily appreciated from the following description of an exemplary embodiment, taken in conjunction with the accompanying drawings of which:

FIG. 1 is a schematic block diagram providing an illustration of a charging device and an electric vehicle which are connected by a charging cable,

FIG. 2 is a flowchart of an exemplary embodiment of a sequence for the method, and

FIG. 3 is a schematic block diagram of an exemplary embodiment of an apparatus.

### DETAILED DESCRIPTION OF THE PREFERRED EMBODIMENT

Reference will now be made in detail to the preferred embodiments, examples of which are illustrated in the accompanying drawings, wherein elements having the same function and mode of action are provided with the same reference symbols in the figures.

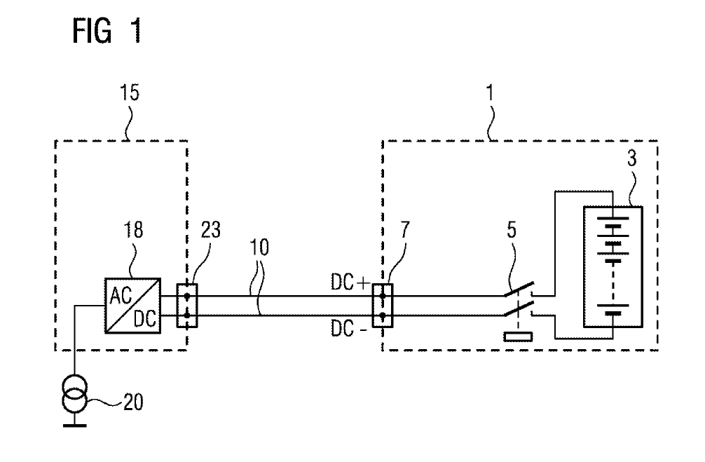

The right-hand side of FIG. 1 shows a detail from an electric vehicle 1. This schematic illustration essentially shows just a battery 3 of the electric vehicle for storing the electric power required for driving the electric vehicle, inter alia. This battery 3 is electrically connected to a contact 7 of the electric car 1 via a switch 5. The switch 5 is in the form of a DC contactor or in the form of a DC load disconnector, for example. In the exemplary embodiment, this contact 7 is a socket or jack which can have the charging cable connected to it in order to charge or discharge the battery 3.

For the purpose of charging or discharging the battery 3, the contact 7 of the electric vehicle 1 can be electrically connected to a charging device 15 by a charging cable 10. By way of example, the charging device 15 may be a charging post which is set up in public places or may be a “chargepoint” at a charging station. In the exemplary embodiment, the electric vehicle 1 (to be more precise the battery 3 of the electric vehicle 1) is charged with direct current, which is routed to the electric vehicle via the charging cable 10. Of the charging device 15, there is a merely schematic illustration of an AC/DC converter 18, the AC connection of which is connected to an AC source 20 (for example an AC power supply system at an AC voltage of 400 V). The DC connection of the AC/DC converter 18 can be connected to the charging cable 10 by a contact 23 of the charging device 15. In the exemplary embodiment, the charging cable 10 is connected both to the contact 23 of the charging device 15 and to the contact 7 of the electric vehicle 1.

In the method and the apparatus, before the beginning of the actual charging process the charging device 15 is electrically connected to the electric vehicle 1 by the charging cable 10. The electric vehicle 1 contains the switch 5 directly downstream of the contact 7 from an electrical point of view, the switch isolating the battery 3 from the contact 7. When the charging cable 10 is being connected to the contact 7, the switch 5 is open. When the charging cable is connected and the switch 5 continues to be open, the charging device 15 checks whether there is a short circuit in the electrical connection (charging cable) to the vehicle. This short circuit may have been caused by a manipulated or faulty contact 7, for example, or by a manipulated or faulty charging cable 10 (i.e. in the power cables of the charging cable 10 or in the charging connectors of the charging cable 10). The contacts 7 and 23 and the electrical connection between contact 7 and switch 5 are likewise checked for the presence of a short circuit. If the charging device 15 detects a short circuit, the charging device 15 outputs an appropriate fault signal and thus communicates the short circuit to the electric vehicle 1, inter alia. Furthermore, the charging device 5 changes to a state in which the charging process cannot be started.

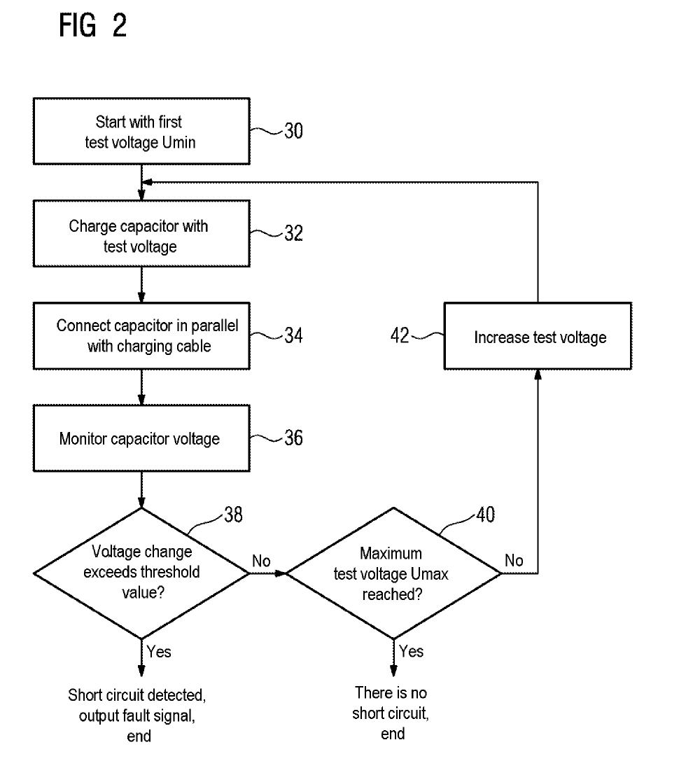

FIG. 2 uses a flowchart to provide a more detailed description of the short-circuit detection method taking place in the charging device 15. First of all, a first voltage value (minimum voltage value Umin) is chosen for the test voltage (30). Next, a capacitor is charged with this test voltage (32). Next, the capacitor is connected in parallel with the charging cable, i.e. one pole of the capacitor is connected to a conductor in the charging cable and the other pole of the capacitor is connected to a second conductor in the charging cable (34). This applies the test voltage which is present on the capacitor to the charging cable.

The voltage which is present on the charging cable is then monitored during a predetermined period of time (36). In this case, the predetermined period of time may be between 0.1 s and 0.5 s, for example. The value by which the voltage which is present on the charging cable (and hence also on the capacitor) changes during the predetermined period of time is measured. In other words, what is measured is the amount by which the voltage which is present on the charging cable and the capacitor falls during the predetermined period of time. If this voltage change/voltage fall exceeds a predetermined threshold (threshold value), there is a short circuit or a state similar to a short circuit (38, Yes alternative). In this case, a short circuit is thus detected and an appropriate fault signal is output. If the voltage change does not exceed the threshold (38, No alternative), a check is first of all performed to determine whether the test voltage has already reached a maximum voltage value Umax (40). If this is the case (40, Yes alternative), the method is terminated with the result that there is no short circuit. If the maximum test voltage Umax has not yet been reached, however, the test voltage is increased (42). Next, the capacitor is charged with the (increased) test voltage (32) and the subsequent operations are executed again.

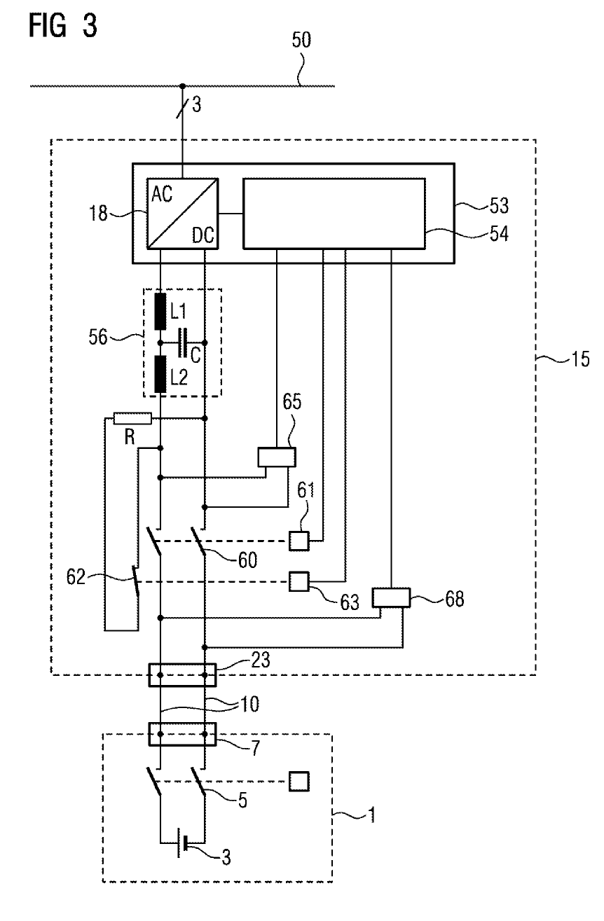

FIG. 3 shows an apparatus for detecting the short circuit. In a manner consistent with FIG. 1, FIG. 3 shows the charging device 15, the electric vehicle 1 and the charging cable 10 which connects the charging device and the electric vehicle.

The upper portion of FIG. 3 shows an AC source in the form of an AC power supply system 50 which is connected to the charging device 15 by a three-pole line. In this case, the AC source 50 is connected to the AC input of the AC/DC converter 18. The AC/DC converter 18 is part of a converter unit 53, which is a six-pulse thyristor converter in the exemplary embodiment. This converter unit 53 contains a controller 54 for the AC/DC converter 18, inter alia.

The DC output of the AC/DC converter 18 is connected to a switch 60 via a low-pass filter 56. The switch 60 is operated by a motor drive 61 (motor actuator). In the exemplary embodiment, the low-pass filter 56 includes two inductances L1 and L2 and a capacitor C. At the output of the low-pass filter 56, the two DC-carrying lines are connected to one another by a disconnectable resistor R. This shunt resistor R is connected or disconnected by a switch 62. The switch 62 is operated by a motor drive 63 (motor actuator). In addition, a first voltmeter 65 (voltage sensor) is provided which measures the level of the DC voltage which is output by the converter 18 between the output of the low-pass filter and the switch 60. Furthermore, a second voltmeter 68 is provided which measures the level of the DC voltage downstream of the switch 60 in relation to the converter. This voltage measured by the second voltmeter 68 corresponds to the voltage which is present on the charging cable 10.

The first voltmeter 65 and the second voltmeter 68 output appropriate measured values to the converter unit 53, where the measured values are processed further in the controller 54.

In another exemplary embodiment, the converter unit 53 used may also be a PWM-controlled converter (PWM=pulse width modulation) having a transistor bridge (e.g. an IGBT bridge), the DC connection of which has no low-pass filter but rather just an electrical capacitor arranged on it as an output capacitor. This capacitor can then also be used for short-circuit detection. The method takes place in the apparatus as follows: when the switch 60 is open and the switch 62 is closed (i.e. the switches 60 and 62 are in the switching position shown in FIG. 3), the first test voltage Umin appears on the capacitance/capacitor C of the low-pass filter 56 (and hence on the shunt resistor R). During the first test iteration, the test voltage is in the low voltage range, i.e. the test voltage has a value of less than or equal to 42 V, for example Umin=12 V. The DC output of the converter 18 is then switched to high impedance and almost simultaneously (i.e. in sync with the few ms of time difference) the switch 60 of the charging device 15 is closed and the switch 62 is opened. At the same time as the switch 60 is being closed, the resistor R is thus disconnected, i.e. the circuit path containing the resistor R is interrupted. The capacitor voltage (which corresponds to the test voltage) is now present on the charging cable 10. Next, the first voltmeter 65 measures the voltage which is present on the charging cable 10 over a prescribed period of time, which may generally be between 0.1 s and 0.5 s (e.g. 0.3 s). The voltage measured values are processed in the controller 54 of the converter unit 53. Alternatively, the voltage can also be measured by the second voltmeter 68, or both voltmeters 65 and 68 can measure the voltage simultaneously as redundant voltmeters.

If the measured voltage falls too quickly over the period of time, i.e. if the voltage change exceeds a threshold, this is detected by the converter unit 53. It is thus detected that there is a short circuit or a state similar to a short circuit. The converter unit 53 then outputs an appropriate fault signal. This fault signal is transmitted to the electric vehicle 1. The charging device 15 then changes to a fault state. In this fault state, the battery of the electric vehicle cannot be charged.

However, if the result of the evaluation of the voltage measured values in the converter unit 53 is that the voltage change in the case of the test voltage Umin does not exceed the threshold, it is detected that there is no short circuit or no state similar to a short circuit. In this case, the method sequence begins afresh with an increased test voltage. The switch 60 is thus opened. At the same time, the switch 62 is closed and hence the resistor R is connected. The converter unit then outputs an increased test voltage at the DC output. The further operations are repeated accordingly.

When the maximum test voltage has been reached and none of the test voltages have detected a short circuit, the short-circuit test is deemed to have been passed overall. The switch 60 is then opened again. The charging device 15 uses an appropriate signal to notify the electric vehicle 1 that the charging device 15 is ready to charge, and allows the electric vehicle 1 to close the switch 5 at the vehicle end. The charging process can now be started by virtue of the converter 18 transmitting direct current to the battery 3 via the switch 60, which can then be closed again. This direct current can then be used to charge the battery.

The maximum test voltage is between 100% and 400% of the maximum charge voltage of the battery. In the exemplary embodiment, the maximum charge voltage of the battery is 420 V and the maximum test voltage is 462 V; the maximum test voltage is 110% of the maximum charge voltage.

A method and an apparatus have been described for detecting a short circuit in a charging cable which is provided for line-based (conductive) charging of the battery of an electric vehicle.

A description has been provided with particular reference to preferred embodiments thereof and examples, but it will be understood that variations and modifications can be effected within the spirit and scope of the claims which may include the phrase “at least one of A, B and C” as an alternative expression that means one or more of A, B and C may be used, contrary to the holding in Superguide v. DIRECTV, 358 F3d 870, 69 USPQ2d 1865 (Fed. Cir. 2004).

1-9. (canceled)

10. A method for detecting a short circuit in a charging cable which can be connected to an electrical charging device to charge a battery of an electric vehicle, comprising:
choosing a first voltage value as a test voltage;
applying the test voltage to the charging cable in testing whether the charging cable or a contact connected to the charging cable is short circuited;
outputting a fault signal upon detection of a short circuit;
increasing the test voltage in steps up to a maximum voltage value when no short circuit is detected during said applying and using respective step increases of the test voltage in testing whether the charging cable or the contact connected to the charging cable is short circuited; and
determining whether the charging cable or the contact connected to the charging cable is short circuited by
charging a capacitor with the test voltage;
applying the test voltage which is present on the capacitor to the charging cable;
monitoring the voltage which is present on the charging cable for a predetermined period of time;
detecting the short circuit when a voltage change which occurs during the period of time exceeds a predetermined threshold value; and
detecting that there is no short circuit when the voltage change which occurs during the period of time does not exceed the predetermined threshold value.

11. The method as claimed in claim 10, wherein the method is terminated with an indication of no short circuit when the test voltage has reached the maximum voltage value and each test voltage has detected no short circuit.

12. The method as claimed in claim 11, wherein the first voltage value is between 1 volt and 42 volts.

13. The method as claimed in claim 12, wherein the maximum voltage value is between 100% and 400% of a maximum charge voltage of the battery of the electric vehicle.

14. The method as claimed in claim 13, further comprising initiating the method by connecting the charging cable to the contact of the electric vehicle while preventing a flow of current between the contact of the electric vehicle and the battery of the electric vehicle.

15. The method as claimed in claim 14, further comprising not sending a current flow enable signal from the charging device to the electric vehicle until after the method has been terminated with the indication of no short circuit.

16. An apparatus for detecting a short circuit in a charging cable which can be connected to an electrical charging device to charge a battery of an electric vehicle, comprising:
a capacitor; and
at least one processor programmed to control a method of
choosing a first voltage value as a test voltage;
applying the test voltage to the charging cable in testing whether the charging cable or a contact connected to the charging cable is short circuited;
outputting a fault signal upon detection of a short circuit;
increasing the test voltage in steps up to a maximum voltage value when no short circuit is detected while applying the test voltage, in testing whether the charging cable or the contact connected to the charging cable is short circuited; and
determining whether the charging cable or the contact connected to the charging cable is short circuited by
charging the capacitor with the test voltage;
applying the test voltage which is present on the capacitor to the charging cable;
monitoring the voltage which is present on the charging cable for a predetermined period of time;
detecting the short circuit when a voltage change which occurs during the period of time exceeds a predetermined threshold value; and
detecting that there is no short circuit when the voltage change which occurs during the period of time does not exceed the predetermined threshold value.

17. The apparatus as claimed in claim 16, wherein the apparatus is part of the charging device.

18. The apparatus as claimed in claim 17, further comprising a low-pass filter including said capacitor and via which a current flowing through the charging cable flows.
